(19) United States
(12) Patent Application Publication
(10) Pub. No.: US 2010/0300505 A1
(43) Pub. Date: Dec. 2, 2010

(54) Multiple junction photovolatic devices and process for making the same

(76) Inventor: Yung T. Chen, Davenport, FL (US)

Correspondence Address: Bing K.YEN, 10689 Deep Cliffe Dr., Cupertino, CA, 95014, US

(21) Appl. No.: 12/454,881

(22) Filed: May 26, 2009

(51) Int. Cl. H01L 31/042; H01L 21/20

(52) U.S. Cl. 136/244; 438/97; 257/E21.09; 977/773

(57) ABSTRACT

A photovoltaic device having multiple photoelectric conversion cells disposed in a tandem configuration and a chemical vapor deposition method for fabricating the same are disclosed. Each photoelectric conversion cell has a different band gap energy and includes a p-type semiconductor layer, an intrinsic semiconductor layer and an n-type semiconductor layer in sequential touching contact. Each semiconductor layer is formed of a nano-crystalline semiconductor containing silicon as a principal constituent. The semiconductor layer may be deposited by a novel chemical vapor deposition method which utilizes plasma and laser energies simultaneously to decompose a film forming gas, thereby forming a semiconductor film on a substrate. The chemical vapor deposition process may be carried out on a continuously conveying substrate, thereby permitting high throughput production of the photovoltaic device.

### FIELD OF THE INVENTION

The present invention relates to photovoltaic devices having at least two photoelectric conversion cells arranged in a tandem configuration and more particularly to cells made of silicon and silicon alloys and process for making the same.

### BACKGROUND OF THE INVENTION

Photovoltaic technology offers great potential as an alternative source of electrical energy. Conventional thin film photovoltaic devices for converting optical energy into electrical energy usually include a photoelectric conversion cell interposed between two electrodes. The photoelectric conversion cell usually comprises at least two layers of semiconductors films having opposite conductivity types, i.e. p-type and n-type. The cell may also have three semiconductor layers having different conductivity types to thereby form a p-i-n junction. The photoelectric conversion efficiency of a cell markedly depends on the band gap energy of the main semiconductor layer. If the band gap energy is high, then the radiant energy from the red and near infrared part of the solar spectrum cannot be absorbed by the cell. Conversely, if the band gap energy is low, then a significant amount of the radiant energy from the ultra violet and blue part of the solar spectrum cannot be properly absorbed by the cell and is lost in the form of heat. As such, the design of the band gap energy for a photoelectric conversion cell is a tradeoff between the absorption of low energy photons and the efficient photoelectric conversion of high energy photons. It is difficult for photovoltaic devices having only one photoelectric conversion cell (i.e. single junction) to fully utilize the entire solar spectrum in an efficient manner.

One way to improve the utilization of the solar spectrum as described above is to arrange two or more cells in a tandem configuration, thereby forming photovoltaic devices having multiple cells, i.e. multiple junctions or multijunctions. These multiple junction devices typically employ at least one cell made of hydrogenated amorphous silicon (a-Si:H) semiconductors because a-Si:H can be fabricated over large area substrates in a cost effective manner as required by photovoltaic applications. However, conventional a-Si:H based cells are plagued by comparatively low conversion efficiencies of less than 7% and light-induced degradation also known as Staebler-Wronski effect. An alternative silicon based thin film semiconductor which has higher conversion efficiencies and reduced light-induced degradation is hydrogenated nano-crystalline silicon (nc-Si:H). Because nc-Si:H has lower optical absorption coefficient in the visible range of the solar spectrum, however, the nc-Si:H layer in solar cells needs to be 3 to 10 times thicker than that required of a-Si:H, making nc-Si:H based cells comparatively more costly to produce using conventional film deposition techniques such as chemical vapor deposition (CVD).

Among various methods for depositing silicon thin films over large area substrates, plasma-enhanced chemical vapor deposition (PECVD) which utilizes a capacitively coupled radio frequency (RF) discharge has emerged to be the dominant method for forming a-Si:H layers in the production of photovoltaic and thin film transistor (TFT) devices. Although a-Si:H based photovoltaic devices have been commercially produced by PECVD for years, the production of comparatively thicker nc-Si:H layers by conventional PECVD is disadvantageously limited by the PECVD deposition rate. The film forming rate in the PECVD process may be increased by increasing the RF power input, which increases the number of ionized film forming gas molecules and the energy thereof. As the film forming rate of nc-Si:H is increased by increasing the RF power input, however, the bombardment of the growing nc-Si:H film on the substrate by highly energized ions also increases, thereby generating film structural defects which have deleterious effects on electrical properties of the film.

A problem associated with conventional single junction photovoltaic devices which have only one photoelectric conversion cell as described above is that these devices cannot fully utilize the entire solar spectrum in an efficient manner.

Another problem associated with forming of nano-crystalline silicon semiconductor layers for photovoltaic devices as described above is that the conventional PECVD method is comparatively slow and is thus not cost effective for production of nano-crystalline silicon based photovoltaic devices, particularly devices comprising multiple cells.

### SUMMARY OF THE INVENTION

The present invention addresses the drawbacks of conventional single junction photovoltaic devices noted above and provides improved devices having multiple photoelectric cells arranged in a tandem configuration and a high rate chemical vapor deposition process for making the same.

Accordingly, an object of the present invention is to provide a photovoltaic device having two photoelectric conversion cells arranged in a tandem configuration. Each cell has a different band gap energy and includes a p-type semiconductor layer, an intrinsic semiconductor layer and an n-type semiconductor layer in sequential touching contact. Each semiconductor layer is formed of a nano-crystalline semiconductor containing silicon as a principal constituent. The first cell has a band gap energy in the range of about 1.6 eV to about 1.9 eV and the second cell has a band gap energy in the range of about 0.7 eV to about 1.2 eV.

Another object of the present invention is to provide a photovoltaic device having three photoelectric conversion cells arranged in a tandem configuration. Each cell has a different band gap energy and includes a p-type semiconductor layer, an intrinsic semiconductor layer and an n-type semiconductor layer in sequential touching contact. Each semiconductor layer is formed of a nano-crystalline semiconductor containing silicon as a principal constituent. The first cell has a band gap energy in the range of about 1.7 eV to about 2.0 eV, the second cell has a band gap energy in the range of about 1.4 eV to about 1.6 eV and the third cell has a band gap energy in the range of about 0.7 eV to about 1.2 eV.

Yet another object of the present invention is to provide a method for depositing a nano-crystalline semiconductor layer containing silicon as a principal constituent for a photoelectric conversion cell. The method comprises the steps of conveying a substrate into a reaction chamber; introducing a film forming gas into the reaction chamber; and generating a plasma in the reaction chamber by ionizing the film forming gas for decomposing the same while simultaneously emitting a laser into the reaction chamber through an incidence window for decomposing the film forming gas, thereby forming a film on the substrate. The film deposition process may be carried out on a substrate which is continuously conveyed in the reaction chamber.

The objects, features, aspects, and advantages of the present invention are readily apparent from the following detailed description of the preferred embodiments for carrying out the invention when taken in connection with the accompanying drawings.

### BRIEF DESCRIPTION OF THE DRAWINGS

FIG. 1 is a cross sectional schematic view of a multiple junction photovoltaic device having two photoelectric conversion cells arranged in a tandem configuration according to the present invention;

FIG. 2 is a cross sectional view of a photoelectric conversion cell including an intrinsic semiconductor layer which has a multilayer structure;

FIG. 3 is a cross sectional schematic view of a multiple junction photovoltaic device having three photoelectric conversion cells arranged in a tandem configuration according to the present invention;

FIG. 4 is a cross sectional view of another photoelectric conversion cell including an intrinsic semiconductor layer which has a multilayer structure;

FIG. 5 is a cross sectional schematic view of a chemical vapor deposition apparatus in accordance with the present invention;

FIGS. 6A and 6B are schematic views showing examples for a laser source which generates a laser sheet according to the CVD apparatus in FIG. 5;

FIG. 7 is a cross sectional schematic view of another chemical vapor deposition apparatus in accordance with the present invention;

FIG. 8 is a cross sectional schematic view of a chemical vapor deposition apparatus for coating a continuously conveying substrate in accordance with the present invention; and

FIG. 9 is another view of the apparatus taken from line 9-9 of FIG. 8.

For purposes of clarity and brevity, like elements and components will bear the same designations and numbering throughout the Figures.

### DETAILED DESCRIPTION OF THE INVENTION

The present invention overcomes the inability of the conventional single junction photovoltaic device to effectively utilize the entire solar spectrum by the spectrum splitting or multiple band gap approach, in which multiple cells having different band gap energies are arranged in a tandem configuration to effectively absorb photons from a wider range of the solar spectrum.

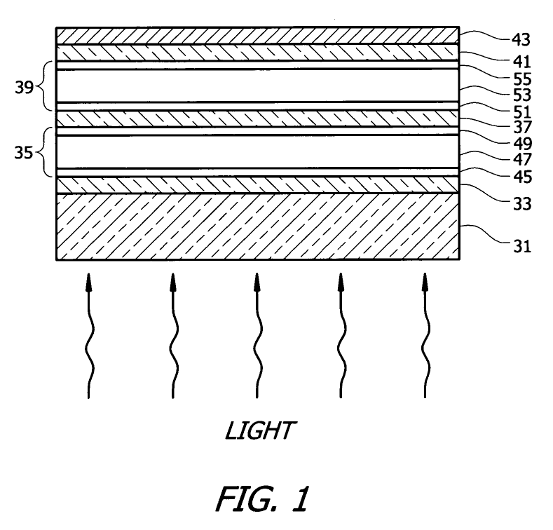

The present invention as applied to a double junction photovoltaic device having two photoelectric conversion cells arranged in a tandem configuration will now be described with reference to FIG. 1. Referring now to FIG. 1, the illustrated device has an optically transparent dielectric substrate 31, through which radiant energy or sunlight enters the device; a layer of a textured transparent front contact 33 formed of a transparent conductive oxide (TCO) material disposed on the substrate 31; a first photoelectric conversion cell 35 having a band gap energy in the range of about 1.6 eV to about 1.9 eV disposed on the transparent front contact 33 for converting the incident light to charge carriers; a layer of a transparent intermediate contact 37 formed of a transparent conductive oxide (TCO) material disposed on the first cell 35 for electrically connecting the same to a second photoelectric conversion cell 39 having a band gap energy in the range of about 0.7 eV to about 1.2 eV; a layer of a transparent back contact 41 formed of a TCO material in contiguous contact with the second cell 39 for collecting light generated charge carriers; and a layer of a textured metal reflector 43 formed of silver (Ag) or aluminum (Al) disposed on the back contact 41.

The double junction device illustrated in FIG. 1 is constructed in the “superstrate” configuration in which the substrate 31 acts as the input window for receiving sunlight and provides support for the device layers during fabrication and operation. The transparent dielectric substrate 31, preferably made of soda-lime or borosilicate glass, also provides protection for the device from impact and elements while allowing maximum transmission of sunlight.

The front contact 33 collects light generated charge carriers while permitting sunlight to pass therethrough. As such, the front contact 33 is preferably formed of a doped TCO material, such as fluorine doped tin oxide (SnO₂:F) or aluminum doped zinc oxide (ZnO:Al), and is sputter deposited onto the substrate 31. The thickness of the front contact 33 is between 0.5 μm and 2 μm, depending on the sheet resistance and transmission requirements.

The first photoelectric conversion cell 35, i.e. the cell that first receives incident light, comprises a p-type semiconductor layer 45 having a thickness in the range of about 10 nm to about 30 nm, an intrinsic (i-type) semiconductor layer 47 having a thickness in the range of about 1 μm to about 3 μm and an n-type semiconductor layer 49 having a thickness in the range of about 10 nm to about 30 nm. The three layers 45-49 are in sequential touching contact and form a p-i-n junction structure. The band gap energy of the first cell 35 (1.6 to 1.9 eV) is mostly determined by that of the comparatively thicker intrinsic layer 47. The three layers 45-49 are formed of nano-crystalline materials containing silicon as a principal constituent and can be deposited by methods including CVD and sputter deposition.

The function of the intermediate contact 37 is to electrically connect the two cells 35 and 39 while permitting the transmittance of sunlight. As such, the intermediate contact 37 is preferably formed of a doped TCO material, such as fluorine doped tin oxide (SnO₂:F) or aluminum doped zinc oxide (ZnO:Al) and is sputter deposited onto the n-type layer 49 of the first cell 35. The thickness of the intermediate contact 37 is between about 0.5 μm and about 1 μm, depending on electrical resistance and optical transmission requirements.

The second photoelectric conversion cell 39 comprises a p-type semiconductor layer 51 having a thickness in the range of about 10 nm to about 30 nm, an intrinsic (i-type) semiconductor layer 53 having a thickness in the range of about 1 μm to about 3 μm and an n-type semiconductor layer 55 having a thickness in the range of about 10 nm to about 30 nm. The three layers 51-55 are in sequential touching contact and form a p-i-n junction structure. Compared with the band gap energy of the first cell 35, the lower band gap energy of the second cell 39 (about 0.7 eV to about 1.2 eV) is mostly determined by that of the intrinsic layer 53. The three layers 51-55 are formed of nano-crystalline materials containing silicon as a principal constituent and can be deposited by methods including CVD and sputter deposition.

The function of the transparent back contact 41 is to collect light generated charge carriers while permitting the transmittance of light which has not been absorbed by the cells 35 and 39. Such light is then reflected back to the same cells 35 and 39 by the metal reflector 43 through the back contact 41 again for further absorbance. As such, the back contact 41 is preferably formed of a doped TCO material, such as fluorine doped tin oxide (SnO₂:F) or aluminum doped zinc oxide (ZnO:Al) and is sputter deposited onto the n-type layer 55 of the second cell 39. The thickness of the back contact 41 is between about 0.5 μm and about 1 μm, depending on the sheet resistance and transmission requirements. The metal reflector 43 is made of an opaque material such as Ag or Al.

In one embodiment according to the present invention of the double junction photovoltaic device illustrated in FIG. 1, the p-type layer 45 and the n-type layer 49 of the first cell 35 are formed of hydrogenated nano-crystalline silicon carbon materials, nc-Si₁₋ₓCₓ:H, where x ranges from more than zero to less than one. The undoped intrinsic layer 47 has an optical band gap in the range of about 1.6 eV to about 1.9 eV and is formed of a hydrogenated nano-crystalline silicon carbon germanium material, nc-Si_{1-y}CₓGe_{y}:H, where x ranges from about 0.3 to about 0.4 and y ranges from about 0.1 to about 0.3. The layers 51-55 of the second cell 39 are formed of hydrogenated nano-crystalline silicon (nc-Si:H) materials.

In another embodiment according to the present invention of the double junction photovoltaic device illustrated in FIG. 1, the p-type layer 45 and the n-type layer 49 of the first cell 35 are formed of hydrogenated nano-crystalline silicon carbon materials, nc-Si₁₋ₓCₓ:H, where x ranges from more than zero to less than one. The undoped intrinsic layer 47 has an optical band gap in the range of about 1.6 eV to about 1.9 eV and is formed of nc-Si₁₋ₓCₓ:H, where x ranges from about 0.3 to about 0.5. The layers 51-55 of the second cell 39 are formed of hydrogenated nano-crystalline silicon germanium materials, nc-Si₁₋ₓGeₓ:H, where x ranges from more than zero to less than one. The band gap energy of the nc-Si₁₋ₓGeₓ:H for the intrinsic layer 55 is in the range of about 0.7 eV to about 0.9 eV.

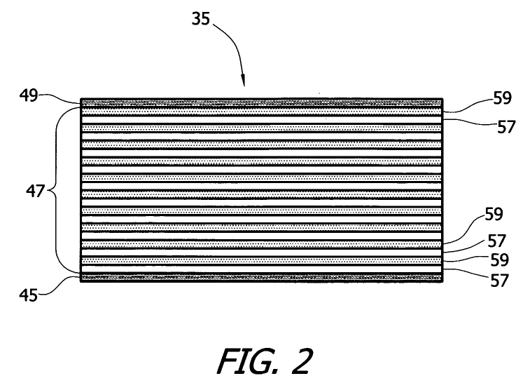

In yet another embodiment according to the present invention of the double junction photovoltaic device illustrated in FIG. 1, the p-type layer 45 and the n-type layer 49 of the first cell 35 having thicknesses in the range of about 10 nm to about 20 nm are formed of nc-Si₁₋ₓCₓ:H materials, where x ranges from more than zero to less than one. The layers 51-55 of the second cell 39 are formed of nc-Si:H materials. The undoped intrinsic layer 47 of the first cell 35 has a multilayer structure as illustrated in FIG. 2, in which numerals 35 and 45-49 denote the same components as those shown for the photovoltaic device of FIG. 1. With continuing reference to FIG. 2, the intrinsic layer 47 comprises a plurality of alternating layers of nc-Si₁₋ₓCₓ:H 57 and nc-Si_{1-y}Ge_{y}:H 59, where x and y range from more than zero to less than one. The thickness of each nc-Si₁₋ₓCₓ:H layer 57 is in the range of about 20 nm to about 30 nm, and the thickness of each nc-Si_{1-y}Ge_{y}:H layer 59 is in the range of about 10 nm to about 20 nm. The overall effective composition and hence the corresponding optical band gap energy of the intrinsic layer 47 are controlled by adjusting the thicknesses of the nc-Si₁₋ₓCₓ:H layer 57 and nc-Si_{1-y}Ge_{y}:H layer 59 such that the resultant intrinsic layer 47 contains 35 to 45 atomic percent (at. %) carbon, 10 to 30 at. % germanium and the balance silicon, thereby forming a semiconductor having an effective band gap energy in the range of about 1.6 eV to about 1.9 eV. The preferred overall thickness of the intrinsic layer 47 in the range of 1 to 6 μm may be attained by stacking 60 to 350 alternating layers of nc-Si₁₋ₓCₓ:H 57 and nc-Si_{1-y}Ge_{y}:H 59.

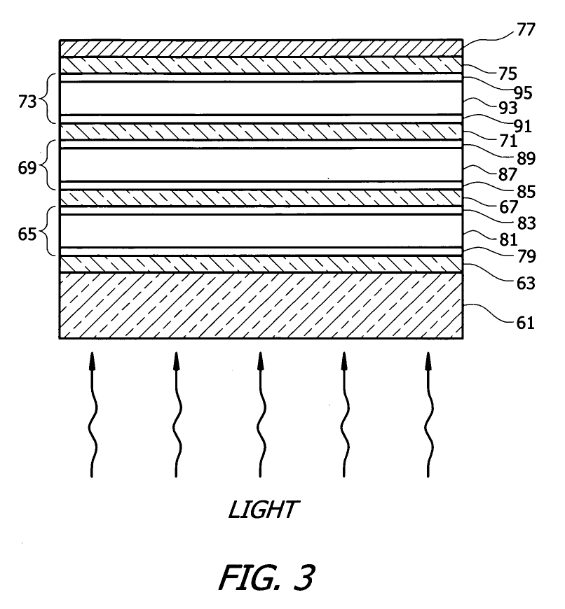

The efficiency of the photovoltaic device may be furthered improved by utilizing a triple junction structure. The present invention as applied to a triple junction photovoltaic device having three photoelectric conversion cells arranged in a tandem configuration will now be described with reference to FIG. 3. The photovoltaic device comprises an optically transparent dielectric substrate 61, through which radiant energy or sunlight enters the device; a layer of a textured transparent front contact 63 formed of a transparent conductive oxide (TCO) material disposed on the substrate 61; a first photoelectric conversion cell 65 having a band gap energy in the range of about 1.7 eV to about 2.0 eV disposed on the transparent front contact 63 for converting the incident light to charge carriers; a layer of a first transparent intermediate contact 67 formed of a transparent conductive oxide (TCO) material disposed on the first cell 65 for electrically connecting the same to a second photoelectric conversion cell 69 having a band gap energy in the range of about 1.4 eV to about 1.6 eV; a layer of a second transparent intermediate contact 71 formed of a TCO material disposed on the second cell 69 for electrically connecting the same to a third photoelectric conversion cell 73 having a band gap energy in the range of about 0.7 eV to about 1.2 eV; a layer of a transparent back contact 75 formed of a TCO material in contiguous contact with the third cell 73 for collecting light generated charge carriers; and a layer of textured metal reflector 77 formed of silver (Ag) or aluminum (Al) disposed on the back contact 75.

The triple junction device illustrated in FIG. 3 is constructed in the “superstrate” configuration in which the substrate 61 acts as the input window for receiving sunlight and provides support for the device layers during fabrication and operation. The transparent dielectric substrate 61, preferably made of soda-lime or borosilicate glass, also provides protection for the device from impact and elements while allowing maximum transmission of sunlight.

The transparent front contact 63 transmits sunlight therethrough and collects light generated charge carriers. As such, the front contact 63 is preferably formed of a doped TCO material, such as fluorine doped tin oxide (SnO₂:F) or aluminum doped zinc oxide (ZnO:Al), and is sputter deposited onto the substrate 61. The thickness of the front contact 63 is in the range of about 0.5 μm to about 1 μm, depending on the sheet resistance and transmission requirements.

The first photoelectric conversion cell 65, i.e. the cell that first receives incident light, comprises a p-type semiconductor layer 79 having a thickness in the range of about 10 nm to about 30 nm, an intrinsic (i-type) semiconductor layer 81 having a thickness in the range of about 1 μm to about 3 μm and an n-type semiconductor layer 83 having a thickness in the range of about 10 nm to about 30 nm. The three semiconductor layers 79-83 are formed of nc-Si₁₋ₓCₓ:H materials, where x ranges from more than zero to less than one, and are in sequential touching contact to thereby form a p-i-n junction structure. The band gap energy of the first cell 65 is in the range of about 1.7 eV to about 2.0 eV as determined by that of the comparatively thicker intrinsic nc-Si₁₋ₓCₓ:H layer 81. The three layers 79-83 of Si₁₋ₓCₓ:H materials may be deposited by various methods including CVD and sputter deposition.

The first intermediate contact 67 transmits sunlight therethrough and electrically connects the first cell 65 to the second cell 69. As such, the first intermediate contact 67 is preferably formed of a doped TCO material, such as fluorine doped tin oxide (SnO₂:F) or aluminum doped zinc oxide (ZnO:Al), and is sputter deposited onto the n-type layer 83 of the first cell 65. The thickness of the first intermediate contact 67 is between about 0.5 μm and about 1 μm, depending on electrical resistance and optical transmission requirements.

The second photoelectric conversion cell 69 comprises a p-type semiconductor layer 85 having a thickness in the range of about 10 nm to about 30 nm, an intrinsic (i-type) semiconductor layer 87 having a thickness in the range of about 1 μm to about 3 μm and an n-type semiconductor layer 89 having a thickness in the range of about 10 nm to about 30 nm. The three layers 85-89 are in sequential touching contact to thereby form a p-i-n junction structure. The band gap energy of the second cell 69 (about 1.4 to about 1.6 eV) as determined by the intrinsic layer 87 thereof is lower than that of the first cell 65. The three layers 85-89 are formed of nano-crystalline materials containing silicon as a principal constituent and can be deposited by various methods including CVD and sputter deposition.

The second intermediate contact 71 transmits sunlight therethrough and electrically connects the second cell 69 to the third cell 73. As such, the second intermediate contact 71 is preferably formed of a doped TCO material, such as fluorine doped tin oxide (SnO₂:F) or aluminum doped zinc oxide (ZnO:Al), and is sputter deposited onto the n-type layer 89 of the second cell 69. The thickness of the second intermediate contact 71 is between about 0.5 μm and about 1 μm, depending on electrical resistance and optical transmission requirements.

The third photoelectric conversion cell 73 comprises a p-type semiconductor layer 91 having a thickness in the range of about 10 nm to about 30 nm, an intrinsic (i-type) semiconductor layer 93 having a thickness in the range of about 1 μm to about 3 μm and an n-type semiconductor layer 95 having a thickness in the range of about 10 nm to about 30 nm. The three layers 91-95 are in sequential touching contact to thereby form a p-i-n junction structure. The band gap energy of the third cell 73 (about 0.7 eV to about 1.2 eV) as determined by the intrinsic layer 93 thereof is lower than those of the first cell 65 and the second cell 69. The three layers 91-95 are formed of nano-crystalline materials containing silicon as a principal constituent and can be deposited by methods including CVD and sputter deposition.

The function of the transparent back contact 75 is to collect light generated charge carriers while permitting the transmittance of light which has not been absorbed by the three cells 65, 69 and 73. Such light is then reflected back to the same cells 65, 69 and 73 by the metal reflector 77 through the transparent back contact 75 again for further absorbance. As such, the back contact 75 is preferably formed of a doped TCO material, such as fluorine doped tin oxide (SnO₂:F) or aluminum doped zinc oxide (ZnO:Al), and is sputter deposited onto the n-type layer 95 of the third cell 73. The thickness of the back contact 75 is between about 0.5 μm and about 1 μm, depending on the sheet resistance and transmission requirements. The metal reflector 77 is made of an opaque material such as Ag or Al.

In one embodiment according to the present invention of the triple junction photovoltaic device illustrated in FIG. 3, the p-type layer 85 and the n-type layers 89 of the second cell 69 are formed of nc-Si₁₋ₓCₓ:H materials, where x ranges from more than zero to less than one. The undoped intrinsic layer 87 has an optical band gap in the range of about 1.4 eV to about 1.6 eV and is formed of a nc-Si_{1-x-y}CₓGe_{y}:H material, where x ranges from about 0.25 to about 0.35 and y ranges from about 0.15 to about 0.35. The layers 91-95 of the third cell 73 are formed of nc-Si:H materials which have band gap energies in the range of about 1.0 to about 1.2 eV.

In another embodiment according to the present invention of the triple junction photovoltaic device illustrated in FIG. 3, the three layers 85-89 of the second cell 69 are formed of nc-Si:H materials. The band gap energy of the second cell 69 as determined by the intrinsic nc-Si:H layer 87 thereof is in the range of about 1.0 to about 1.2 eV. The layers 91-95 of the third cell 73 are formed of nc-Si₁₋ₓGeₓ:H materials, where x ranges from more than zero to less than one. The band gap energy of the third cell 93 is in the range of about 0.7 eV to about 0.9 eV.

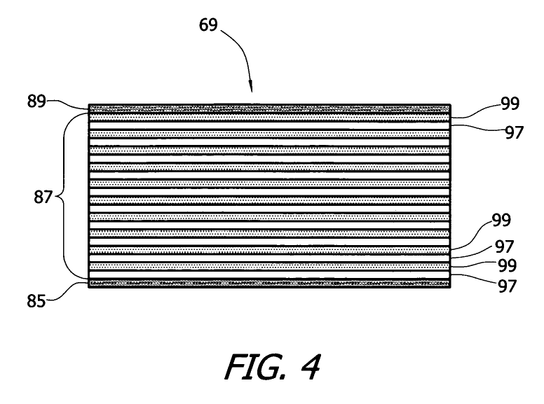

In yet another embodiment according to the present invention of the triple junction photovoltaic device illustrated in FIG. 3, the p-type layer 85 and the n-type layer 89 of the second cell 69 having thicknesses in the range of about 10 nm to about 20 nm are formed of nc-Si₁₋ₓCₓ:H materials, where x ranges from more than zero to less than one. The layers 91-95 of the third cell 73 are formed of nc-Si:H materials which have band gap energies in the range of about 1.0 eV to about 1.2 eV. The undoped intrinsic layer 87 of the second cell 69 has a multilayer structure as illustrated in FIG. 4, in which numerals 69 and 85-99 denote the same components as those shown for the photovoltaic device of FIG. 3. With continuing reference to FIG. 4, the intrinsic layer 87 comprises a plurality of alternating layers of nc-Si₁₋ₓCₓ:H 97 and nc-Si_{1-y}Ge_{y}:H 99, where x and y range from more than zero to less than one. The thickness of each nc-Si₁₋ₓCₓ:H layer 97 is in the range of about 20 nm to about 30 nm and the thickness of each nc-Si_{1-y}Ge_{y}:H layer 99 is in the range of about 10 nm to about 20 nm. The overall effective composition and hence the corresponding optical band gap energy of the intrinsic layer 87 are controlled by adjusting the thicknesses of the nc-Si₁₋ₓCₓ:H layer 97 and the nc-Si_{1-y}Ge_{y}:H layer 99 such that the resultant intrinsic layer 87 contains 25 to 35 at. % carbon, 15 to 35 at. % germanium and the balance silicon, thereby forming a semiconductor having an effective band gap energy in the range of about 1.4 eV to about 1.6 eV. The preferred overall thickness of the intrinsic layer 87 in the range of about 1 to 6 μm may be attained by stacking together 60 to 350 alternating layers of nc-Si₁₋ₓCₓ:H 97 and nc-Si_{1-y}Ge_{y}:H 99.

The semiconductor layers 45-55 and 79-95 for the double junction photovoltaic device (FIG. 1) and the triple junction photovoltaic device (FIG. 3), respectively, may be deposited by plasma enhanced chemical vapor deposition (PECVD). In the PECVD process a glow discharge or plasma is employed to excite and decompose molecules of a film forming gas, causing decomposed molecules to condense onto a substrate to thereby form a film thereon. Nano-crystalline semiconductor films containing silicon as a principal constituent, such as nc-Si:H, nc-Si₁₋ₓCₓ:H, nc-Si_{1-y}Ge_{y}:H and nc-Si_{1-x-y}CₓGe_{y}:H described above, may be deposited by PECVD using appropriate film forming gases. For example, a nc-Si:H semiconductor film can be deposited by using a film forming gas comprising gaseous hydrogen and at least one silicon containing gaseous compound selected from the group consisting of monosilane (SiH₄), disilane (Si₂H₆), trisliane (Si₃H₈), silicon tetrafluoride (SiF₄), silicon tetrachloride (SiCl₄), monomethylsilane (SiH₃CH₃), hexamethyldisilane (Si₂(CH₃)₆), dichlorosilane (H₂SiCl₂) and trichlorosilane (HSiCl₃). A nc-Si₁₋ₓCₓ:H semiconductor film may be deposited by PECVD using a film forming gas comprising gaseous hydrogen, the above silicon containing gaseous compound and a carbon containing gaseous compound selected from the group consisting of methane (CH₄), acetylene (C₂H₂), ethylene (C₂H₄), ethane (C₂H₆), propylene (C₃H₆) and propane (C₃H₈). A nc-Si_{1-y}Ge_{y}:H semiconductor film may be deposited by PECVD using a film forming gas comprising gaseous hydrogen, the above silicon containing gaseous compound and a germanium containing gaseous compound selected from the group consisting of germane (GeH₄), monomethylgermane (GeH₃CH₃) and dimethylgemane (GeH₂(CH₃)₂). A nc-Si_{1-x-y}CₓGe_{y}:H semiconductor film can be deposited by using a film forming gas comprising gaseous hydrogen, the above silicon containing gaseous compound, the above carbon containing gaseous compound and the above germanium containing gaseous compound. The ratio of gaseous hydrogen to other gaseous compounds in the forming gas is greater than 10 for forming nano-crystalline films. The film forming gas may further include a gaseous dopant compound such as diborane (B₂H₂) or trimethylborane (B(CH₃)₃) for forming a p-type semiconductor or a gaseous dopant compound such as phosphine (PH₃) or phosphorus trichloride (PCl₃) for forming an n-type semiconductor.

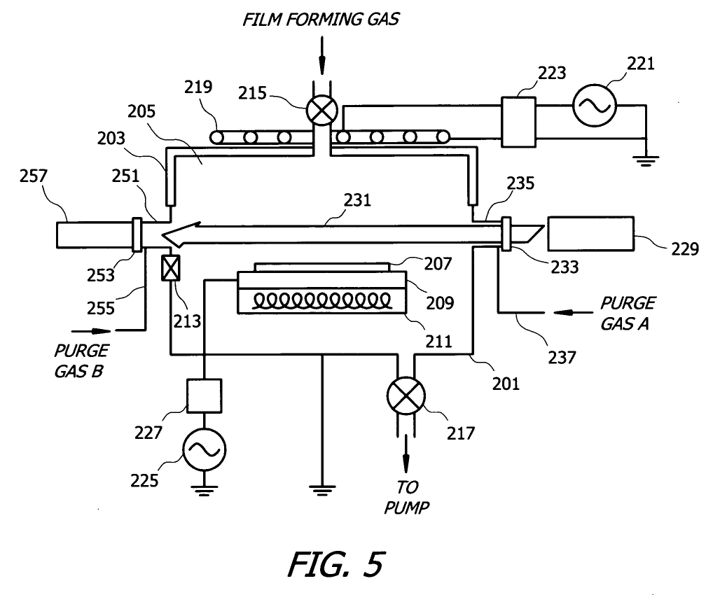

In an embodiment at least one of the semiconductor layers 45-55 and 79-95 for the double junction photovoltaic device (FIG. 1) and the triple junction photovoltaic device (FIG. 3), respectively, is deposited by a novel high-speed chemical vapor deposition apparatus which utilizes a combination of plasma and optical energy to excite and decompose the film forming gas as illustrated in FIG. 5. Referring now to FIG. 5, the apparatus has a vessel base 201, which is preferably constructed of a suitably strong and conductive material such as stainless steel and is electrically grounded, and a vessel top or dome 203 made of a dielectric material such as aluminum oxide or aluminum nitride. The base 201 and the dome 203 together define a reaction chamber 205 therein.

With continuing reference to FIG. 5, a generally flat substrate 207 for coating a film thereon is placed inside the reaction chamber 205. The substrate 207 is supported by a mounting base 209 which also serves as a bias electrode. A suceptor 211 for heating the substrate 207 is attached to the bottom surface of the mounting base 209 and incorporates therein a heating element which may be energized from a current source (not shown) external to the chamber 205. The substrate 207 is transported in and out of the chamber 205 through a shutter 213 disposed on the sidewall of the vessel base 201. A film forming gas is introduced into the chamber 205 through an inlet valve 215. The post-reaction gas in the chamber 205 is evacuated by a pumping system (not shown) through a gate valve 217 which also controls the chamber pressure.

An antenna 219 which is formed in a spiral coil is disposed in close proximity to the top of the vessel dome 203 for inducing a high frequency electric field in the reaction chamber 205, thereby generating a gaseous plasma by ionization of the forming gas therein. A radio frequency (RF) power supply 221, preferably having an excitation frequency of 1 to 108.48 MHz, provides energy to the antenna 219 through an impedence matching network 223 which matches the output impedence of the RF power supply 221 with the antenna 219 in a manner as well known to one of skill in the art. A planar bias electrode 209 which also serves as the mounting base for supporting the substrate 207 is used to enhance the transport of plasma species (e.g., ions) generated by the antenna 219 to the surface of the substrate 207. The electrically grounded vessel base 201 serves as the complimentary electrode to the bias electrode 209. A RF power supply 225, preferably having an excitation frequency of 13.56 MHz or lower, provides power to the bias electrode 209 via a bias matching network 227.

A high-power carbon dioxide (CO₂) laser source 229 disposed outside the reaction chamber 205 is used to emit a laser sheet 231 for exciting and decomposing the film forming gas in the chamber 205. Other types of gas lasers such as excimer laser, argon fluoride (ArF) laser, krypton chloride (KrCl) laser, krypton fluoride (KrF) laser, xenon chloride (XeCl) laser and xenon fluoride (XeF) laser may also be used to emit the laser sheet 231. The laser sheet 231 is transmitted into the reaction chamber 205 through a laser incidence window 233 attached to a laser incidence port 235 which is disposed on the side of the vessel base 201. The incidence window 233 is constructed of a suitably rigid and light-transparent material such as quartz. A purge gas A, preferably an inert gas such as Ar, helium (He), xenon (Xe) or krypton (Kr), is introduced into the cavity of the incidence port 235 via a purge gas delivery line 237, thereby removing the film forming gas in the incidence port 235 and preventing the clouding of the laser incidence window 233 attached thereto. The cavity opening of the incidence port 235 to the reaction chamber 205 in the direction perpendicular to the laser sheet 231 should be sufficiently narrow, preferably less than 5 mm, and the length of the cavity of the incidence port 235 in the propagation direction of the laser sheet 231 should be sufficiently long, preferably longer than 100 mm, thereby preventing the film forming gas in the reaction chamber 205 from reaching the surface of the incidence window 233 by diffusion.

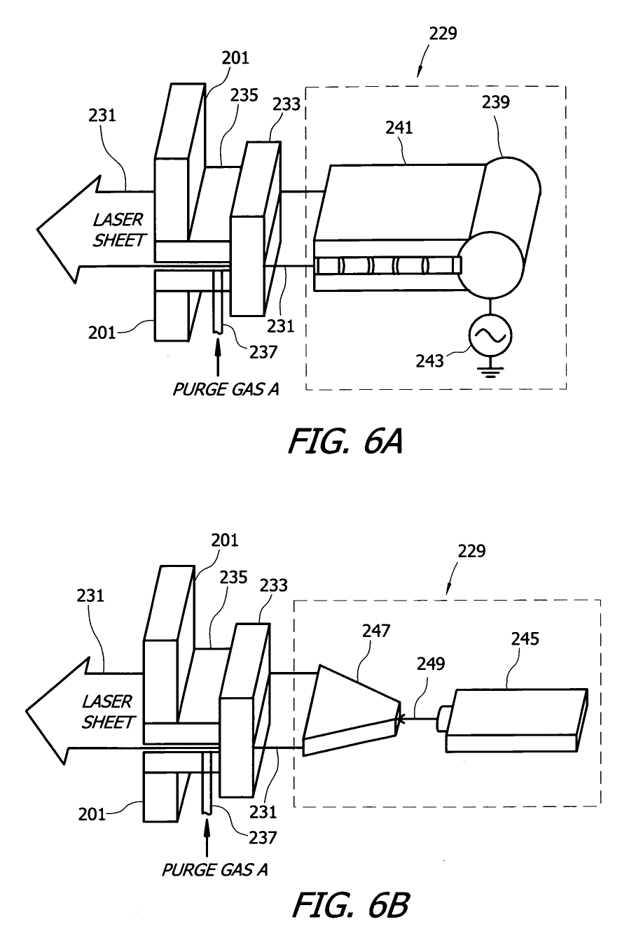

The above laser source 229 for generating the laser sheet 231 may be constructed according to FIGS. 6A or 6B. In the drawings, numerals 201 and 229 to 237 denote the same components or substances as those shown in FIG. 5. FIG. 6A is a schematic illustration showing the laser source 229 which includes a cylindrical laser chamber 239 containing a gain medium therein, an optical system 241 connected thereto and an external RF power source 243 for providing energy to the gain medium. The optical system 241 includes a plurality of optical lenses which have cross sections that are substantially constant along the axis of the cylindrical laser chamber 239. When power is supplied to the laser chamber 239, the gain medium therein emits an electromagnetic wave (e.g. light) which propagates through the set of optical lenses in the optical system 241 to thereby form the laser sheet 231. The laser sheet 231 passes through the incidence window 233 and into the reaction chamber through the incidence port 235. FIG. 6B is a schematic illustration showing an alternative construction of the laser source 229 which includes a conventional beam-type laser source 245 and an optical system 247 for shaping a laser beam 249 generated from the conventional laser source 245 to the laser sheet 231.

Referring again to FIG. 5, the laser sheet 231 passes inside the chamber 205 on a plane which is substantially parallel to the top surface of the substrate 207 and is spaced apart therefrom by a few millimeters. The laser sheet 231 is wider than the substrate 207 in the direction orthogonal to the propagation direction thereof, thereby allowing excitation and decomposition of the film forming gas to occur uniformly over the substrate 207. The laser sheet 231 exits the chamber 205 through a transparent laser emergence window 253 attached to an emergence port 251, which is disposed on the vessel base 201 opposite to the incidence port 235. A purge gas B, preferably an inert gas such as Ar, He, Xe or Kr, is introduced into the cavity of the emergence port 251 via a purge gas delivery line 255, thereby removing the film forming gas in the port 251 and preventing the clouding of the laser emergence window 253 attached thereto. A laser termination unit 257 is attached to the laser emergence window 253 for receiving the laser sheet 231 emerged therefrom. The termination unit 257 includes a power detector (not shown) for measuring the amount of photon energy absorbed by the film forming gas and a plurality of optical lenses and reflective mirrors (not shown) for reflecting the laser sheet 231 back to the reaction chamber 205, thereby further enhancing the excitation and decomposition of the film forming gas therein. The laser termination unit 257 may also be replaced by a laser trap made of a light absorbing material such as carbon for absorbing the laser sheet 231 which has emerged from the emergence window 253.

Operation of the illustrated apparatus of FIG. 5 will now be described for forming a nc-Si:H semiconductor film on a substrate. The reaction chamber 205 is first evacuated to 10⁻⁶-10⁻⁸ Torr by the pumping system through the gate valve 217. With the substrate 207 placed on the mounting base 209 in the reaction chamber 205, the suceptor 211 is used to heat the substrate 207 to a temperature in the range of about 150° C. to about 550° C., preferably 300° C. to about 500° C. When the desired substrate temperature is reached, a film forming gas comprising SiH₄ and H₂ is introduced at a predetermined flow rate into the reaction chamber 205 through the inlet valve 215. The ratio of H₂ to SiH₄ in the film forming gas is greater than 10:1, preferably about 15:1. The pressure of the film forming gas in the chamber 205 is maintained at a level in the range of 10⁻² to 1 Torr, preferably 10⁻² to 10⁻¹ Torr. The high frequency power is then provided to the spiral antenna 219 and the bias electrode 209 by the antenna power supply 221 and the bias electrode power supply 225, respectively, and at the same time a laser sheet 231 is emitted from the laser source 229 into the reaction chamber 205.

The film forming gas in the reaction chamber 205 is converted into a gaseous plasma state upon excitation by the high frequency electric field exerted by the antenna 219. The excited species formed in the plasma, which include ions and partially decomposed molecules, reach the top of the substrate 207 and condense thereon to form a dense nc-Si:H film. The plasma power density is set to a level in the range of about 0.01 to 3 W/cm³, preferably about 0.02 to 1 W/cm³. The plasma power density is a value of the power applied from the antenna power supply 221 to the antenna 219 for plasma generation divided by the volume of plasma generation region in the reaction chamber 205.

The ions in the plasma are accelerated toward the substrate 207 by the electric field exerted by the bias electrode 209, thereby compacting the growing nc-Si:H film. The bias voltage on the electrode 209 is applied by the RF power supply 225 in such a way that ions transported to the substrate surface would have energies less than a predetermined threshold energy (for instance, about 16 eV for Si), beyond which the semiconductor film on the substrate 207 may be damaged by bombardment from high energy ions.

With H₂ and SiH₄ in the reaction chamber 205 being converted into a gaseous plasma state by the antenna 219, the laser sheet 231 which passes atop of the substrate 207 concurrently excites and decomposes SiH₄ molecules along its path in the chamber 205. Under high-rate deposition conditions, such as high laser power and high SiH₄ gas flow rate, exothermic reactions may occur to form discrete nc-Si:H nanoparticles in the gas phase, thereby depositing the same directly on the substrate 207. The simultaneous deposition of discrete nc-Si:H nanoparticles on the substrate 207 by the laser-induced reactions and condensed vapors from the plasma allows the condensation of the excited species in the plasma to fill the gaps between nc-Si:H nanoparticles, thereby forming a non-porous nc-Si:H film with nanoparticles imbedded in a dense matrix. The film forming process is carried out until a desired nc-Si:H thickness in the range of about 1 μm to about 30 μm is reached.

While the above process for forming a nc-Si:H film uses the film forming gas comprising gaseous hydrogen and monosilane (SiH4), a nc-Si:H film may also be deposited by using the above-described process and a film forming gas comprising gaseous hydrogen and a silicon containing gaseous compound selected from the group consisting of Si₂H₆, Si₃H₈, SiF₄, SiCl₄, SiH₃CH₃, Si₂(CH₃)₆, H₂SiCl₂ and HSiCl₃. A nc-Si₁₋ₓCₓ:H semiconductor film may be deposited by using the above-described process and a film forming gas comprising gaseous hydrogen, the above silicon containing gaseous compound and a carbon containing gaseous compound selected from the group consisting of CH₄, C₂H₂, C₂H₄, C₂H₆, C₃H₆ and C₃H₈. A nc-Si_{1-y}Ge_{y}:H semiconductor film may be deposited by the above-described process and a film forming gas comprising gaseous hydrogen, the above silicon containing gaseous compound and a germanium containing gaseous compound selected from the group consisting of GeH₄, GeH₃CH₃ and GeH₂(CH₃)₂. A nc-Si_{1-x-y}CₓGe_{y}:H semiconductor film may be deposited by using the above-described process and a film forming gas comprising gaseous hydrogen, the above silicon containing gaseous compound, the above carbon containing gaseous compound and the above germanium containing gaseous compound. The ratio of gaseous hydrogen to other gaseous compounds in the forming gas is greater than 10 for forming nano-crystalline films. The film forming gas may further include a gaseous dopant compound such as B₂H₂ or B(CH₃)₃ for forming a p-type semiconductor or a gaseous dopant compound such as PH₃ or PCl₃ for forming an n-type semiconductor.

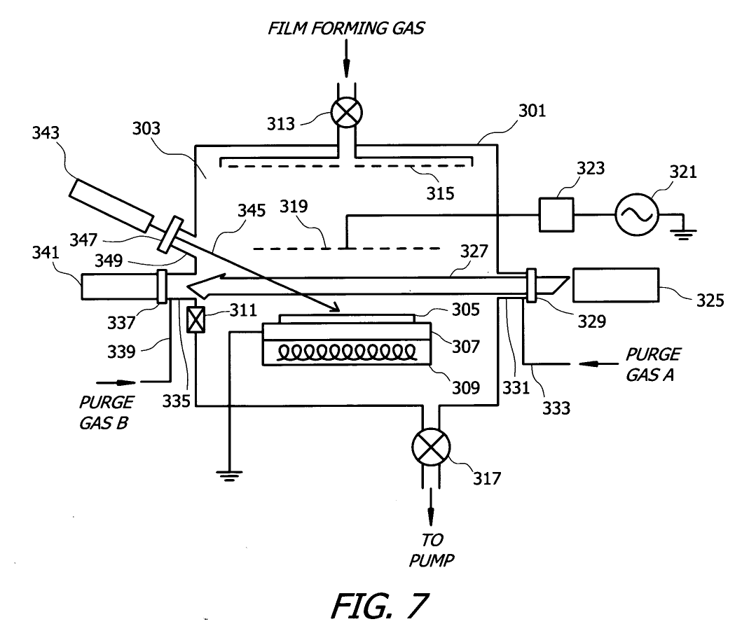

In another embodiment at least one of the semiconductor layers 45-55 and 79-95 for the double junction photovoltaic device (FIG. 1) and the triple junction photovoltaic device (FIG. 3), respectively, is deposited by a novel high-speed chemical vapor deposition apparatus which utilizes a combination of plasma and optical energy to excite and decompose the film forming gas as illustrated in FIG. 7. The apparatus of FIG. 7 is different from the apparatus of FIG. 5 in that a capacitively coupled plasma is used to excite and decompose the film forming gas. The illustrated apparatus in FIG. 7 has a reaction vessel 301 which defines a reaction chamber 303 therein. A generally flat substrate 305 for coating a film thereon is placed inside the reaction chamber 303. The substrate 305 is supported by a mounting base 307 which is preferably made of an electrically conducting metal. A suceptor 309 for heating the substrate 305 is attached to the bottom surface of the mounting base 307 and incorporates therein a heating element which may be energized from a current source (not shown) external to the chamber 303. The substrate 305 is transported in and out of the chamber 303 through a shutter 311 disposed on the sidewall of the vessel 301. A film forming gas is introduced into the chamber 303 through an inlet valve 313 and a gas shower head 315 connected thereto. The gas shower head 315 has a plurality of holes or openings distributed over the bottom surface thereof such that the film forming gas passes therethrough is uniformly distributed in the chamber 303. The post-reaction gas in the chamber 303 is evacuated by a pumping system (not shown) through a gate valve 317 which also controls the chamber pressure.

A planar discharge electrode 319 is disposed on top of the substrate 305 and is generally parallel thereto for generating a plasma by ionizing the film forming gas in the chamber 303. The discharge electrode 319 which is made from a conductive metal is shown as being in the form of screen or mesh, although other configurations such as a solid plate type of construction can also be employed. The mounting base 307 which is grounded acts as the complimentary electrode to the discharge electrode 319. A RF power supply 321, preferably having an operating frequency of 13.56 to 108.48 MHz, provides energy to the discharge electrode 319 through an impedence matching network 323 which is tuned to the impedence of the plasma generated in between the electrodes 319 and 307 as well known to one of skill in the art.

A high-power CO₂ laser source 325 disposed outside the reaction chamber 303 is used to emit a laser sheet 327 for exciting and decomposing the film forming gas in the chamber 303. Other types of gas lasers such as excimer laser, ArF laser, KrCl laser, KrF laser, XeCl laser and XeF laser may also be used to emit the laser sheet 327. The CO₂ laser source 325 may be constructed according to the examples shown in FIGS. 6A and 6B.

With continuing reference to FIG. 7, the laser sheet 327 is transmitted into the reaction chamber 303 through a laser incidence window 329 attached to a laser incidence port 331 which is disposed on the side of the vessel 301. The incidence window 329 is constructed of a suitably rigid and light-transparent material such as quartz. A purge gas A, preferably an inert gas such as Ar, He, Xe or Kr, is introduced into the cavity of the incidence port 331 via a purge gas delivery line 333, thereby flushing out the film forming gas in the port 331 and preventing the clouding of the laser incidence window 329 attached thereto. The cavity opening of the incidence port 331 to the reaction chamber 303 in the direction perpendicular to the laser sheet 327 should be sufficiently narrow, preferably less than 5 mm, and the length of the cavity of the incidence port 331 in the propagation direction of the laser sheet 327 should be sufficiently long, preferably longer than 100 mm, thereby preventing the film forming gas in the reaction chamber 303 from reaching the surface of the incidence window 329 by diffusion.

The laser sheet 327 passes inside the chamber 303 in between the discharge electrode 319 and the substrate 305 on a plane which is substantially parallel to the top surface of the substrate 305 and is spaced apart therefrom by a few millimeters. The laser sheet 327 is wider than the substrate 305 in the direction orthogonal to the propagation direction thereof, thereby allowing excitation and decomposition of the film forming gas to occur uniformly over the substrate 305. The laser sheet 327 exits the chamber 303 through a transparent laser emergence window 337 attached to a laser emergence port 335, which is disposed on the vessel 301 opposite to the incidence port 331. A purge gas B, preferably an inert gas such as Ar, He, Xe or Kr, is introduced into the cavity of the emergence port 335 via a purge gas delivery line 339, thereby removing the film forming gas in the port 335 and preventing the clouding of the laser emergence window 337 attached thereto. A laser termination unit 341 is attached to the laser emergence window 337 for receiving the laser sheet 327 emerged therefrom. The termination unit 341 includes a power detector (not shown) for measuring the amount of photon energy absorbed by the film forming gas and a plurality of optical lenses and reflective mirrors (not shown) for reflecting the laser sheet 327 back to the reaction chamber 303, thereby further enhancing the excitation and decomposition of the film forming gas therein. The laser termination unit 341 may also be replaced by a laser trap made of a light absorbing material such as carbon for absorbing the laser sheet 327 which has emerged from the emergence window 337.

An excimer laser source 343 is disposed outside the chamber 303 for crystallizing a film by irradiating the same on the substrate 305 with a laser beam 345, which passes into the reaction chamber 303 through a light-transparent window 347 attached to a peripheral port 349 on the reaction vessel 301. The excimer laser source 343 is positioned in such a way that allows the laser beam 345 to irradiate the top surface of the substrate 305 in the chamber 303.

Operation of the illustrated apparatus of FIG. 7 will now be described for forming a nc-Si:H film on the substrate 305. The reaction chamber 303 is first evacuated to 10⁻⁶-10⁻⁸ Torr by the pumping system via the gate valve 317. With the substrate 305 placed on the mounting base 307 in the reaction chamber 303, the suceptor 309 is used to heat the substrate 305 to a temperature in the range of about 150° C. to about 550° C., preferably about 300° C. to about 500° C. When the desired substrate temperature is reached, a film forming gas comprising SiH₄ and H₂ is introduced at a predetermined flow rate into the reaction chamber 303 through the gas shower head 315. The pressure of the film forming gas in the chamber 303 is maintained at 10⁻² to 1 Torr, preferably 10⁻¹ to 1 Torr. The high frequency power is then provided to the discharge electrode 319 by the power supply 321, and at the same time a laser sheet 327 is emitted from the CO₂ laser source 325 into the reaction chamber 303.

The film forming gas between the discharge electrode 319 and the ground electrode 307 is converted into a gaseous plasma state upon excitation by the discharge electrode 319. The excited species formed in the plasma, which include ions and partially decomposed molecules, reach the top of the substrate 305 and condense thereon to form a dense nc-Si:H film. The plasma power density is set to be at a level in the range of about 0.01 to 3 W/cm³, preferably about 0.02 to 1 W/cm³. The plasma power density is a value of the power applied from the power supply 321 to the discharge electrode 319 for plasma generation divided by the volume of plasma generation region, which approximately corresponds to the volume in between the discharge electrode 319 and the ground electrode 307.

With a plasma being generated between the electrodes 307 and 319 by ionization of the film forming gas, the laser sheet 327 which passes atop of the substrate 305 concurrently excites and decomposes SiH₄ molecules in the film forming gas along the path of the laser sheet 327 in the chamber 303. Under high-rate deposition conditions, such as high laser power and high gas flow rate, exothermic reactions can occur to form discrete nc-Si:H nanoparticles in the gas phase, thereby depositing the same directly on the substrate 305. The simultaneous deposition of discrete nanoparticles on the substrate 305 by the laser-induced reactions and condensed vapors from the plasma permits the condensation of the excited species from the plasma to fill the gaps between nanoparticles, thereby forming a non-porous nc-Si:H film with nanoparticles imbedded in a dense matrix.

After the nc-Si:H film is formed according to the procedures described above, all power to the discharge electrode 319 and the CO₂ laser 325 for emitting the laser sheet 327 is terminated. The inlet gas valve 313 is closed and the film forming gas in the chamber 303 is evacuated, thereby forming a vacuum therein. Under the above state, power is provided to the excimer laser source 343 for generating the laser beam 345 with a power density in the range of 1 to 15 mW/cm² to irradiate the as-deposited nc-Si:H film on top of the substrate 305, thereby further improving the film crystallinity and electrical properties.

While the above process for forming a nc-Si:H film uses the film forming gas comprising gaseous hydrogen and monosilane (SiH4), a nc-Si:H film may also be deposited by using the above-described process and a film forming gas comprising gaseous hydrogen and a silicon containing gaseous compound selected from the group consisting of Si₂H₆, Si₃H₈, SiF₄, SiCl₄, SiH₃CH₃, Si₂(CH₃)₆, H₂SiCl₂ and HSiCl₃. A nc-Si₁₋ₓCₓ:H semiconductor film may be deposited by using the above-described process and a film forming gas comprising gaseous hydrogen, the above silicon containing gaseous compound and a carbon containing gaseous compound selected from the group consisting of CH₄, C₂H₂, C₂H₄, C₂H₆, C₃H₆ and C₃H₈. nc-Si_{1-y}Ge_{y}:H semiconductor film may be deposited by the above-described process and a film forming gas comprising gaseous hydrogen, the above silicon containing gaseous compound and a germanium containing gaseous compound selected from the group consisting of GeH₄, GeH₃CH₃ and GeH₂(CH₃)₂. A nc-Si_{1-x-y}CₓGe_{y}:H semiconductor film may be deposited by using the above-described process and a film forming gas comprising gaseous hydrogen, the above silicon containing gaseous compound, the above carbon containing gaseous compound and the above germanium containing gaseous compound. The ratio of gaseous hydrogen to other gaseous compounds in the forming gas is greater than 10 for forming nano-crystalline films. The film forming gas may further include a gaseous dopant compound such as B₂H₂ or B(CH₃)₃ for forming a p-type semiconductor or a gaseous dopant compound such as PH₃ or PCl₃ for forming an n-type semiconductor.

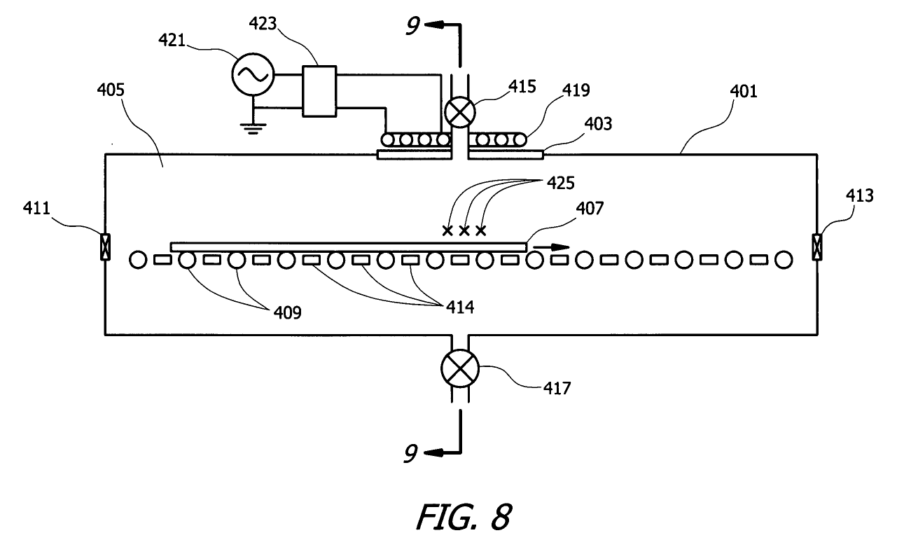

In yet another embodiment at least one of the semiconductor layers 45-55 and 79-95 for the double junction photovoltaic device (FIG. 1) and the triple junction photovoltaic device (FIG. 3), respectively, is deposited by a novel high-speed chemical vapor deposition apparatus which utilizes a combination of plasma and optical energy to excite and decompose the film forming gas as illustrated in FIG. 8. The apparatus of FIG. 8 is different from the apparatus of FIGS. 5 and 7 in that a substrate for depositing a film thereon is continuously conveyed during the film deposition process, thereby permitting high throughput manufacturing operation. Referring now to FIG. 8, the apparatus has a vessel base 401, which is preferably constructed of a suitably strong and conductive material such as stainless steel and is electrically grounded, and a vessel top 403 made of a dielectric material such as aluminum oxide or aluminum nitride. The base 401 and the top 403 together define a reaction chamber 405 therein.

With continuing reference to FIG. 8, a generally flat substrate 407 for coating a film thereon is continuously conveyed by a system of roller conveyor 409 through the reaction chamber 405 from entrance valve 411 to the exit valve 413. A plurality of heaters 414 for heating the substrate 207 from the bottom surface thereof are disposed in between the rollers of the roller conveyor 409. The heaters 414 incorporate therein heating elements which may be energized from a current source (not shown) external to the chamber 405. A film forming gas is introduced into the chamber 405 through an inlet valve 415. The post-reaction gas in the chamber 405 is evacuated by a pumping system (not shown) through a gate valve 417 which also controls the chamber pressure.

An antenna 419 which is formed in a spiral coil is disposed in close proximity to the top of the vessel top 403 for inducing a high frequency electric field in the reaction chamber 405, thereby generating a gaseous plasma by ionizing the forming gas. A radio frequency (RF) power supply 421, preferably having an excitation frequency of 1 to 108.48 MHz, provides energy to the antenna 419 through an impedance matching network 423 which matches the output impedence of the RF power supply 421 with the antenna 419 in a manner as well known to one of skill in the art.

A laser 425 in the form of multiple parallel beams for exciting and decomposing the film forming gas passes inside the chamber 405 on a plane which is substantially parallel to the top surface of the substrate 407 and is spaced apart therefrom by a few millimeters. The laser 425 may also be in the form of a sheet.

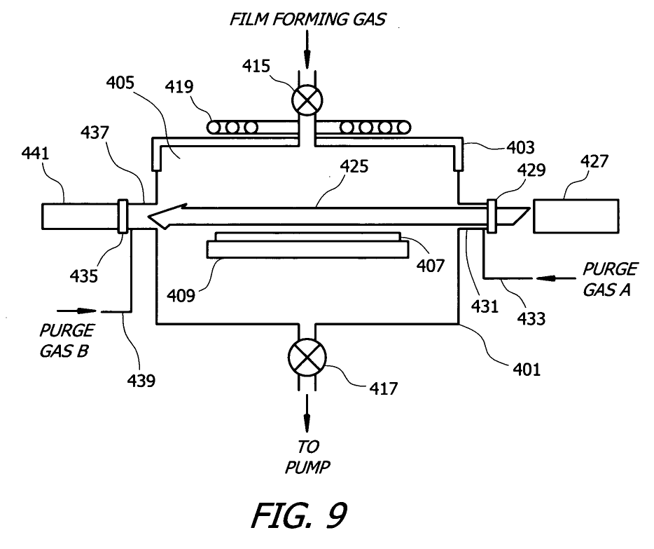

FIG. 9 is another view of the apparatus taken from line 9-9 of FIG. 8. In the drawing numerals 401 to 425 denote the same components or substances as those shown in FIG. 8. Referring now to FIG. 9, a high-power carbon dioxide (CO₂) laser source 427 disposed outside the reaction chamber 405 is used to emit the laser 425 for exciting and decomposing the film forming gas in the chamber 405. Other types of gas lasers such as excimer laser, argon fluoride (ArF) laser, krypton chloride (KrCl) laser, krypton fluoride (KrF) laser, xenon chloride (XeCl) laser and xenon fluoride (XeF) laser may also be used to emit the laser 425. The laser 425 is transmitted into the reaction chamber 405 through a laser incidence window 429 attached to a laser incidence port 431 which is disposed on the side of the vessel base 401. The incidence window 429 is constructed of a suitably rigid and light-transparent material such as quartz. A purge gas A, preferably an inert gas such as Ar, helium (He), xenon (Xe) or krypton (Kr), is introduced into the cavity of the incidence port 431 via a purge gas delivery line 433, thereby removing the film forming gas in the incidence port 431 and preventing the clouding of the laser incidence window 429 attached thereto. The cavity opening of the incidence port 431 to the reaction chamber 405 in the direction perpendicular to the laser 425 should be sufficiently narrow, preferably less than 5 mm, and the length of the cavity of the incidence port 431 in the propagation direction of the laser 425 should be sufficiently long, preferably longer than 100 mm, thereby preventing the film forming gas in the reaction chamber 405 from reaching the surface of the incidence window 429 by diffusion. The laser source 427 may include a plurality of convention laser beam sources for emitting the laser 425 in the form of multiple parallel beams. The laser source 427 may also be constructed according to FIG. 6A or 6B for generating the laser 425 in the form of a sheet.

With continuing reference to FIG. 9, the laser 425 passes inside the chamber 405 on a plane which is substantially parallel to the top surface of the substrate 407 and is spaced apart therefrom by a few millimeters. The laser 425 exits the chamber 405 through a transparent laser emergence window 435 attached to an emergence port 437, which is disposed on the vessel base 401 opposite to the incidence port 431. A purge gas B, preferably an inert gas such as Ar, He, Xe or Kr, is introduced into the cavity of the emergence port 437 via a purge gas delivery line 439, thereby removing the film forming gas in the port 437 and preventing the clouding of the laser emergence window 435 attached thereto. A laser termination unit 441 is attached to the laser emergence window 435 for receiving the laser 425 emerged therefrom. The termination unit 441 includes a power detector (not shown) for measuring the amount of photon energy absorbed by the film forming gas and a plurality of optical lenses and reflective mirrors (not shown) for reflecting the laser 425 back to the reaction chamber 405, thereby further enhancing the excitation and decomposition of the film forming gas therein. The laser termination unit 441 may also be replaced by a laser trap made of a light absorbing material such as carbon for absorbing the laser 425 emerged from the emergence window 435.

It should be noted that the apparatus illustrated in FIGS. 8 and 9 may be a part of a modular processing system comprising a plurality of processing apparatus modules connected in series. The apparatus may be connected to another identical apparatus, an apparatus module for sputter deposition, an apparatus module for heat treatment or a load lock module in such a way that permits successive layers of films to be deposited on the conveying substrate 407, which moves from a previous processing apparatus module into the apparatus through the entrance valve 411 and moves from the apparatus to a next processing module through the exit valve 413 as illustrated in FIG. 8.

Deposition of a nc-Si:H semiconductor film on a continuously conveyed substrate by the apparatus will now be described with combined reference to FIGS. 8 and 9. The reaction chamber 405 is first evacuated to a base pressure, preferably in the range of 10⁻⁶-10⁻⁸ Torr, by pumping through the gate valve 417. The entrance valve 411 and the exit valve 413 then open to permit the entrance of the substrate 407 for coating and the exit of a previously coated substrate, respectively. The substrate 407 is rapidly heated by the heaters 414 to a temperature in the range of about 150° C. to about 550° C., preferably about 300° C. to about 500° C., while being continuously conveyed by the roller conveyer 409 into the reaction chamber 405 through the entrance valve 411. After the substrate 407 has completely passed the entrance valve 411, the valves 411 and 413 are closed again to seal the reaction chamber 405 and the substrate 407 therein. Thereafter, a film forming gas comprising SiH₄ and H₂ is introduced at a predetermined flow rate into the reaction chamber 405 through the inlet valve 415. The ratio of H₂ to SiH₄ in the film forming gas is greater than about 10:1, preferably about 15:1. The pressure of the film forming gas in the chamber 405 is maintained at a level in the range of 10⁻² to 1 Torr, preferably 10⁻² to 10⁻¹ Torr. As the leading edge of the conveying substrate 407 reaches the region below the antenna 419, the high frequency power is provided to the antenna 419 by the antenna power supply 421 and at the same time a laser 425 is emitted from the laser source 427 into the reaction chamber 405.

The film forming gas in the reaction chamber 405 is converted into a gaseous plasma state upon excitation by the high frequency electric field exerted by the antenna 419. The excited species formed in the plasma, which include ions and partially decomposed molecules, reach the top of the substrate 407 and condense thereon to form a dense nc-Si:H film. The plasma power density is set to a level in the range of about 0.01 to 3 W/cm³, preferably 0.02 to 1 W/cm³. The plasma power density is a value of the power applied from the antenna power supply 421 to the antenna 419 for plasma generation divided by the volume of plasma generation region in the reaction chamber 405.

With the H₂ and SiH₄ in the reaction chamber 405 being converted into a gaseous plasma state by the antenna 419, the laser 425 (in the form of multiple parallel beams or a sheet) which passes atop of the substrate 407 concurrently excites and decomposes SiH₄ molecules along its path in the chamber 405. Under high-rate deposition conditions, such as high laser power and high SiH₄ gas flow rate, exothermic reactions may occur to form discrete nc-Si:H nanoparticles in the gas phase, thereby depositing the same directly on the substrate 407. The simultaneous deposition of discrete nc-Si:H nanoparticles on the substrate 407 by the laser-induced reactions and condensed vapors from the plasma allows the condensation of the excited species in the plasma to fill the gaps between nc-Si:H nanoparticles, thereby forming a non-porous nc-Si:H film with nanoparticles imbedded in a dense matrix. The film forming process continues until the entire top surface of the substrate 407 is coated with a dense nc-Si:H film as the substrate 407 is continuously conveyed through the plasma and the region beneath the laser 425.

While the above process for forming a nc-Si:H film uses the film forming gas comprising gaseous hydrogen and monosilane (SiH4), a nc-Si:H film may also be deposited on a continuously conveying substrate by using the above-described process and a film forming gas comprising gaseous hydrogen and a silicon containing gaseous compound selected from the group consisting of Si₂H₆, Si₃H₈, SiF₄, SiCl₄, SiH₃CH₃, Si₂(CH₃)₆, H₂SiCl₂ and HSiCl₃. A nc-Si₁₋ₓCₓ:H semiconductor film may be deposited by using the above-described process and a film forming gas comprising gaseous hydrogen, the above silicon containing gaseous compound and a carbon containing gaseous compound selected from the group consisting of CH₄, C₂H₂, C₂H₄, C₂H₆, C₃H₆ and C₃H₈. A nc-Si_{1-y}Ge_{y}:H semiconductor film may be deposited by the above-described process and a film forming gas comprising gaseous hydrogen, the above silicon containing gaseous compound and a germanium containing gaseous compound selected from the group consisting of GeH₄, GeH₃CH₃ and GeH₂(CH₃)₂. A nc-Si_{1-x-y}CₓGe_{y}:H semiconductor film may be deposited by using the above-described process and a film forming gas comprising gaseous hydrogen, the above silicon containing gaseous compound, the above carbon containing gaseous compound and the above germanium containing gaseous compound. The ratio of gaseous hydrogen to other gaseous compounds in the forming gas is greater than 10 for forming nano-crystalline films. The film forming gas may further include a gaseous dopant compound such as B₂H₂ or B(CH₃)₃ for forming a p-type semiconductor or a gaseous dopant compound such as PH₃ or PCl₃ for forming an n-type semiconductor.

While the present invention has been shown and described with reference to certain preferred embodiments, it is to be understood that those skilled in the art will no doubt devise certain alterations and modifications thereto which nevertheless include the true spirit and scope of the present invention. Thus the scope of the invention should be determined by the appended claims and their legal equivalents, rather than by examples given.

What is claimed is:

1. A photovoltaic device comprising:
a first photoelectric conversion cell including a first p-type semiconductor layer, a first intrinsic semiconductor layer and a first n-type semiconductor layer in sequential touching contact; and
a second photoelectric conversion cell including a second p-type semiconductor layer, a second intrinsic semiconductor layer and a second n-type semiconductor layer in sequential touching contact,
wherein said first cell has a higher band gap energy than said second cell, said semiconductor layers of said cells are formed of nano-crystalline semiconductors containing silicon as a principal constituent.

2. The photovoltaic device of claim 1, wherein said first cell has a band gap energy in the range of about 1.6 eV to about 1.9 eV and said second cell has a band gap energy in the range of about 0.7 eV to about 1.2 eV.

3. The photovoltaic device of claim 1, wherein:
said first p-type semiconductor layer is formed of nc-Si₁₋ₓCₓ:H, where x ranges from more than zero to less than one;
said first intrinsic semiconductor layer is formed of nc-Si_{1-x-y}CₓGe_{y}:H, where x ranges from about 0.3 to about 0.4 and y ranges from about 0.1 to about 0.3;
said first n-type semiconductor layer is formed of nc-Si₁₋ₓCₓ:H, where x ranges from more than zero to less than one;
said second p-type semiconductor layer is formed of nc-Si:H;
said second intrinsic semiconductor layer is formed of nc-Si:H; and
said second n-type semiconductor layer is formed of nc-Si:H.

4. The photovoltaic device of claim 1, wherein:
said first p-type semiconductor layer is formed of nc-Si₁₋ₓCₓ:H, where x ranges from more than zero to less than one;
said first intrinsic semiconductor layer is formed of nc-Si₁₋ₓCₓ:H, where x ranges from about 0.3 to about 0.5;
said first n-type semiconductor layer is formed of nc-Si₁₋ₓCₓ:H, where x ranges from more than zero to less than one;
said second p-type semiconductor layer is formed of nc-Si₁₋ₓGeₓ:H, where x ranges from more than zero to less than one;
said second intrinsic semiconductor layer is formed of nc-Si₁₋ₓGeₓ:H, where x ranges from more than zero to less than one; and
said second n-type semiconductor layer is formed of nc-Si₁₋ₓGeₓ:H, where x ranges from more than zero to less than one.

5. The photovoltaic device of claim 1, wherein:
said first p-type semiconductor layer is formed of nc-Si₁₋ₓCₓ:H, where x ranges from more than zero to less than one;
said first intrinsic semiconductor layer is formed of a plurality of alternating layers of nc-Si₁₋ₓCₓ:H and nc-Si_{1-y}Ge_{y}:H, where x and y range from more than zero to less than one;
said first n-type semiconductor layer is formed of nc-Si₁₋ₓCₓ:H, where x ranges from more than zero to less than one;
said second p-type semiconductor layer is formed of nc-Si:H;
said second intrinsic semiconductor layer is formed of nc-Si:H; and
said second n-type semiconductor layer is formed of nc-Si:H.

6. A triple junction photovoltaic device comprising:
a first photoelectric conversion cell including a first p-type semiconductor layer, a first intrinsic semiconductor layer and a first n-type semiconductor layer in sequential touching contact;
a second photoelectric conversion cell including a second p-type semiconductor layer, a second intrinsic semiconductor layer and a second n-type semiconductor layer in sequential touching contact; and
a third photoelectric conversion cell including a third p-type semiconductor layer, a third intrinsic semiconductor layer and a third n-type semiconductor layer in sequential touching contact,
wherein said first cell has a higher band gap energy than said second cell, said second cell has a higher band gap energy than said third cell, said semiconductor layers of said cells are formed of nano-crystalline semiconductors containing silicon as a main constituent.

7. The photovoltaic device of claim 6, wherein said first cell has a band gap energy in the range of about 1.7 eV to about 2.0 eV, said second cell has a band gap energy in the range of about 1.4 eV to about 1.6 eV and said third cell has a band gap energy in the range of about 0.7 eV to about 1.2 eV.

8. The photovoltaic device of claim 6, wherein said first p-type semiconductor layer, said first intrinsic semiconductor layer and said first n-type semiconductor layer of said first cell are formed of Si₁₋ₓCₓ:H, where x ranges from more than zero to less than one.

9. The photovoltaic device of claim 8, wherein:
said second p-type semiconductor layer is formed of nc-Si₁₋ₓCₓ:H, where x ranges from more than zero to less than one;
said second intrinsic semiconductor layer is formed of nc-Si_{1-x-y}CₓGe_{y}:H, where x ranges from about 0.25 to about 0.35 and y ranges from about 0.15 to about 0.35;
said second n-type semiconductor layer is formed of nc-Si₁₋ₓCₓ:H, where x ranges from more than zero to less than one;
said third p-type semiconductor layer is formed of nc-Si:H;
said third intrinsic semiconductor layer is formed of nc-Si:H; and
said third n-type semiconductor layer is formed of nc-Si:H.

10. The photovoltaic device of claim 8, wherein:
said second p-type semiconductor layer is formed of nc-Si:H;
said second intrinsic semiconductor layer is formed of nc-Si:H;
said second n-type semiconductor layer is formed of nc-Si:H;
said third p-type semiconductor layer is formed of nc-Si₁₋ₓGeₓ:H, where x ranges from more than zero to less than one;
said third intrinsic semiconductor layer is formed of nc-Si₁₋ₓGeₓ:H, where x ranges from more than zero to less than one; and
said third n-type semiconductor layer is formed of nc-Si₁₋ₓGeₓ:H, where x ranges from more than zero to less than one.

11. The photovoltaic device of claim 8, wherein:
said second p-type semiconductor layer is formed of nc-Si₁₋ₓCₓ:H, where x ranges from more than zero to less than one;
said second intrinsic semiconductor layer is formed of a plurality of alternating layers of nc-Si₁₋ₓCₓ:H and nc-Si_{1-y}Ge_{y}:H, where x and y range from more than zero to less than one;
said second n-type semiconductor layer is formed of nc-Si₁₋ₓCₓ:H, where x ranges from more than zero to less than one;
said third p-type semiconductor layer is formed of nc-Si:H;
said third intrinsic semiconductor layer is formed of nc-Si:H; and
said third n-type semiconductor layer is formed of nc-Si:H.

12. A method for depositing a nano-crystalline semiconductor layer containing silicon as a principal constituent for a photoelectric conversion cell, the method comprising the steps of:
supporting a substrate in a reaction chamber;
introducing a film forming gas into said reaction chamber; and
generating a plasma in said reaction chamber by ionizing said film forming gas for decomposing said film forming gas while simultaneously emitting a laser into said reaction chamber through an incidence window for decomposing said film forming gas, thereby forming a film on said substrate.

13. The method of claim 12, wherein said laser is in the form of a sheet and passes in parallel with said substrate along a plane spaced apart therefrom.

14. The method of claim 12, further comprising the step of irradiating the semiconductor film on the substrate surface with an excimer laser, thereby improving the film crystallinity.

15. The method of claim 12, wherein said substrate is continuously conveyed in said reaction chamber during the film forming process.

16. The method of claim 15, further comprising the step of heating said substrate to a temperature in the range of about 250° C. to about 500° C. prior to introducing said film forming gas into said reaction chamber.

17. The method of claim 15, wherein said laser is in the form of a sheet and passes in parallel with said substrate along a plane spaced apart therefrom.

18. The method of claim 15, wherein said laser is in the form of at least one beam and passes in parallel with said substrate along a plane spaced apart therefrom.

19. The method of claim 15, wherein said film forming gas comprises gaseous hydrogen and a silicon containing gaseous compound selected from the group consisting of SiH₄, Si₂H₆, Si₃H₈, SiF₄, SiCl₄, SiH₃CH₃, Si₂(CH₃)₆, H₂SiCl₂ and HSiCl₃.

20. The method of claim 15, wherein an inert gas is blown against said incidence window for preventing clouding of said incidence window during film formation process.
